(19) United States
(12) Patent Application Publication
(10) Pub. No.: US 2009/0033374 A1
(43) Pub. Date: Feb. 5, 2009

(54) Clock generator

(76) Inventors: John Paul Lesso, Edinburgh (GB); John Laurence Pennock, Midlothian (GB)

Correspondence Address: DICKSTEIN SHAPIRO LLP, 1825 EYE STREET NW, Washington, DC, 20006-5403, US

(21) Appl. No.: 12/219,129

(22) Filed: Jul. 16, 2008

(30) Foreign Application Priority Data
Jul. 31, 2007 (GB) 0714888.5

(51) Int. Cl. H03B 21/02; H03K 23/00

(52) U.S. Cl. 327/105; 327/115

(57) ABSTRACT

A frequency divider, comprising an input for receiving an input clock signal having a first frequency; a divider, for generating an output signal having an instantaneous frequency equal to the first frequency divided by an instantaneous division ratio; and a sequence generator, for generating a sequence of instantaneous division ratios by adding a sequence of instantaneous dither values to an integer value. The instantaneous division ratios in the sequence have a mean value that is equal to an integer desired ratio, but none of the instantaneous division ratios in the sequence is equal to the integer desired ratio.

### BACKGROUND OF THE INVENTION

1. Field of the Invention

The present invention relates to clock generation, and particularly, but not exclusively, relates to clock generation for power converters.

2. Description of the Related Art

Power converters are well-known sources of electromagnetic interference. Switching converters and DC-DC converters, when clocked at frequencies in the order of megahertz, will generate substantial tones at the fundamental frequency and its harmonics.

These tones may cause problems for other components in the system. Electromagnetic (EM) pulses radiated from the chip may cause malfunction in other parts of the system. Further, in audio applications, the tones may react with non-linearities in the system and mix down in frequency, creating tones that are audible to the user.

FIG. 1 shows a standard power converter system 10. An incoming voltage Vᵢₙ is input to a power converter 20 and converted to an output voltage Vₒᵤₜ, with the converter 20 being clocked at a frequency f_{c}. Vₒᵤₜ may be greater than Vᵢₙ (as in boost converters) or less than Vᵢₙ (as in buck converters). The clock frequency f_{c} is generated by dividing a signal of fixed frequency f_{REF} in a ÷N block 30.

FIG. 2 is a schematic graph showing the problem of tone generation in power converters. Sharp tones are created at the clock frequency f_{c} and its odd harmonics. The generation of tones at the odd harmonics arises from the Fourier transform of the square wave clock. As aforementioned, these tones are undesirable.

### SUMMARY OF THE INVENTION

According to a first aspect of the present invention, there is provided a frequency divider, comprising an input for receiving an input clock signal having a first frequency; a divider, for generating an output signal having an instantaneous frequency equal to the first frequency divided by an instantaneous division ratio; and a sequence generator, for generating a sequence of instantaneous division ratios by adding a sequence of instantaneous dither values to an integer value. The instantaneous division ratios in said sequence have a mean value that is equal to an integer desired ratio, but none of the instantaneous division ratios in said sequence is equal to the integer desired ratio.

According to a second aspect of the present invention, there is provided a frequency divider, comprising an input for receiving an input clock signal having a first frequency; a divider, for generating an output signal having an instantaneous frequency equal to the first frequency divided by an instantaneous division ratio; a word length reduction block, for receiving a fractional component of a non-integer desired ratio and outputting a sequence of instantaneous modulated outputs; and a sequence generator, for generating a sequence of instantaneous division ratios by summing a sequence of instantaneous dither values, said sequence of instantaneous modulated outputs and an integer value. The non-integer desired ratio is equal to the sum of an integer component and said fractional component, said fractional component being less than one. The instantaneous division ratios in said sequence have a mean value that is equal to the non-integer desired ratio. A partial sum of the integer value and the sequence of instantaneous dither values does not equal the integer component of the non-integer desired ratio.

According to a third aspect of the present invention, there is provided a method of frequency synthesis, comprising the steps of: receiving an input signal having a first frequency; generating a sequence of instantaneous division ratios by adding a sequence of instantaneous dither values to an integer value; generating an output signal having an instantaneous frequency equal to the first frequency divided by an instantaneous division ratio. The instantaneous division ratios in said sequence have a mean value that is equal to an integer desired ratio, but none of the instantaneous division ratios in said sequence is equal to the integer desired ratio.

According to a fourth aspect of the present invention, there is provided a method of frequency synthesis, comprising the steps of: receiving an input signal having a first frequency; receiving a fractional component of a non-integer desired ratio and outputting a sequence of instantaneous modulated outputs; generating a sequence of instantaneous division ratios by summing a sequence of instantaneous dither values, said sequence of instantaneous modulated outputs and an integer value; and generating an output signal having an instantaneous frequency equal to the first frequency divided by an instantaneous division ratio. The non-integer desired ratio is equal to the sum of an integer component and said fractional component, said fractional component being less than one. The instantaneous division ratios in said sequence have a mean value that is equal to the non-integer desired ratio. A partial sum of the integer value and the sequence of instantaneous dither values does not equal the integer component of the non-integer desired ratio.

### BRIEF DESCRIPTION OF THE DRAWINGS

For a better understanding of the present invention, and to show more clearly how it may be carried into effect, reference will now be made, by way of example, to the following drawings, in which:

FIG. 1 is a block schematic diagram, illustrating the general form of a power converter circuit.

FIG. 2 illustrates tones generated in a power converter circuit.

FIG. 3 is a block schematic diagram, illustrating a clock modulation circuit, acting as a frequency divider.

FIG. 4 illustrates tones generated in the circuit of FIG. 3.

FIG. 5 is a block schematic diagram, illustrating a further clock modulation circuit, acting as a frequency divider, in accordance with an aspect of the present invention.

FIG. 6 is a block schematic diagram, illustrating a further clock modulation circuit, acting as a frequency divider, in accordance with an aspect of the present invention.

FIG. 7 is a more detailed block schematic diagram, illustrating the frequency divider block in the circuits of FIGS. 5 and 6.

FIG. 8 illustrates the operation of the frequency divider block of FIG. 7.

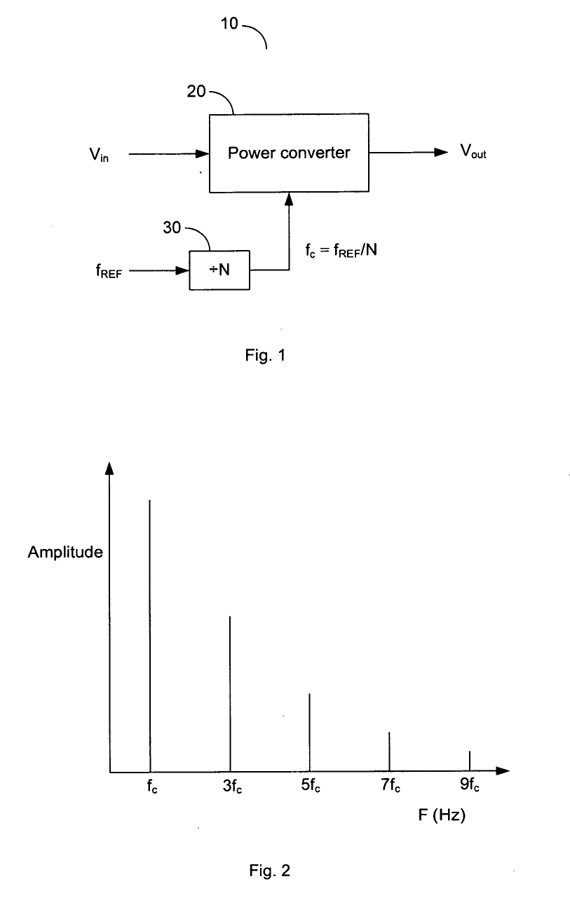

### DETAILED DESCRIPTION OF THE PREFERRED EMBODIMENT

One solution to the generation of the unwanted tones generated by the power converter is to modulate the clock frequency by applying some form of dither. Dither is a noise signal that is intentionally added to a signal. In some applications, dither is used to increase the accuracy of a truncated signal. In the present application, the dither is used to slightly spread the clock frequency so that not all of the energy radiated by the power converter is concentrated on the clock frequency and its harmonics. That is, the distribution of power is spread over a range of frequencies and hence the peaks are reduced.

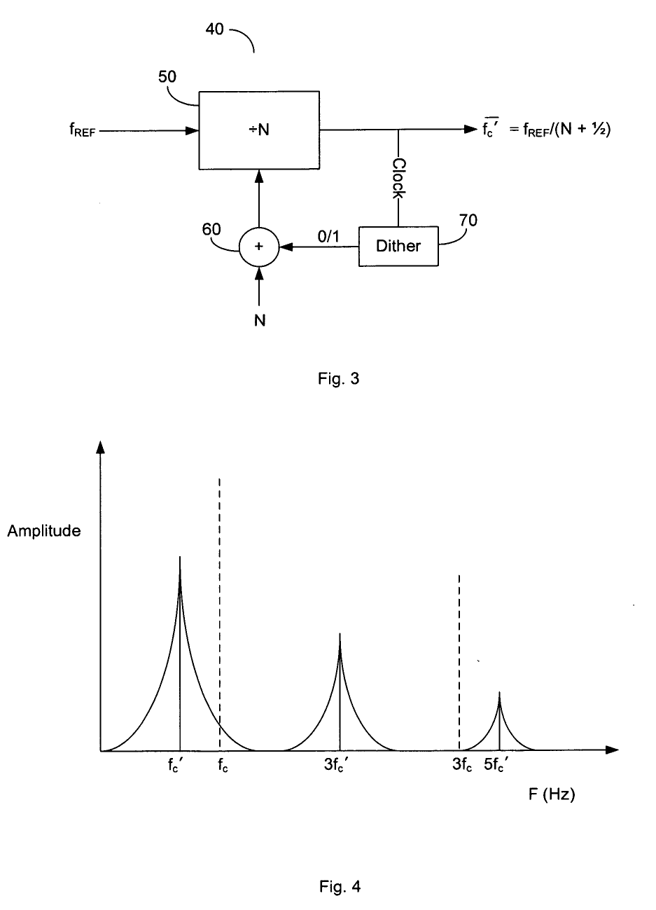

FIG. 3 shows a first clock modulation circuit 40.

The circuit 40 comprises a ÷N block 50 which receives an input signal at a reference frequency f_{REF}. An adding element 60 adds a desired division factor N and a dither signal generated by a 1-bit dither block 70, and outputs the sum to the ÷N block 50.

The ÷N block 50 generates an output clock signal at an instantaneous frequency which is f_{REF} divided by the output of the adding element 60. This output signal is also used to clock the dither block 70.

The dither block 70 may comprise one or more of a number of random number generators that will be familiar to one skilled in the art and need not be explained in great detail here. For example, the dither block 70 may comprise a linear feedback shift register, or a loop circuit with an unstable feedback loop.

Thus, in the one-bit case shown here, randomly generated 1s and 0s are added to N to shift slightly the output frequency of the system. The effect of this dither is to spread the peaks at the clock frequency and its harmonics, so that not all of the power of the system is concentrated at the discrete frequencies.

The circuit 40 has a drawback, however. The average output of the dither block 70 is approximately ½, so on average the division factor will increase to N+½, and the average output clock frequency of the system will be reduced. That is, the average output frequency of the first clock generation circuit 40 is in fact f_{c}′=f_{REF}/(N+½).

FIG. 4 is a schematic graph showing this effect in more detail. The dashed lines show the previous positions of the tones. As can be clearly seen, the new clock frequency f_{c}′ and its harmonics are lower in frequency than they previously would have been. Such a reduction in frequency is also undesirable. However, the amplitude of the peaks is reduced and therefore the tones will not be as audible to an end user as they otherwise would have been.

One solution to the problem of reducing the frequency of the clock is to increase the number of bits of dither to at least two. In this instance, the possible dither outputs will be −1, 0 or +1, and the average dither output is zero. However, this does not reduce the amplitude of the peaks sufficiently.

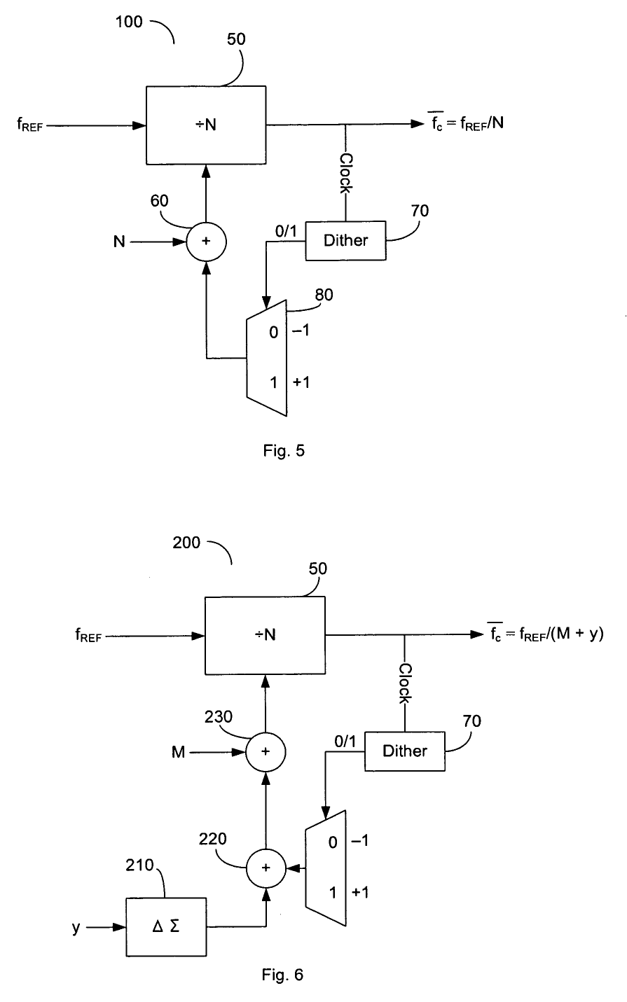

FIG. 5 shows a second clock generation circuit 100. The second clock generation circuit 100 is generally similar to the first clock generation circuit 40. However, the dither is applied in a different way. Similar components in the two circuits 40, 100 have similar reference numerals and therefore will not be described in further detail.

In this embodiment, the output of the dither block 70 is input to a multiplexer 80, and the multiplexer 80 outputs the dither signal to the adding element 60. The multiplexer 80 functions to receive the 1-bit output of the dither block 70, and then select a dither signal of either −1 or +1. So, for example, if the output of the dither block is 0, the multiplexer may output −1, and if the dither is 1, the multiplexer may output +1.

As before, the ÷N block 50 generates an output clock signal at an instantaneous frequency which is equal to the input frequency f_{REF} divided by the output of the adding element 60. This output signal is also used to clock the dither block 70. In this case, the average dither applied to the division factor is 0, and so the average frequency of the output clock signal is not shifted, and is equal to f_{REF}/N.

However, a further important point of the circuit 100 is that none of the possible outputs of the multiplexer 80 is zero. So, although the average output is zero, none of the instantaneous outputs is zero. The instantaneous frequency output of the ÷N block 50 is therefore always slightly perturbed, either positively or negatively.

By never applying zero dither, the amplitudes of the tones at the central peaks of f_{c} and its harmonics are minimized.

Variations on the circuit 100 may be thought of by one skilled in the art without departing from the scope of the invention. For example, advantageously, the applied dither may be +2 and −2, so that the peak is spread even further. If a two-bit dither signal was used, the dither outputs may be chosen as −5, −2, +2 and +5, for example. Higher numbers of bits of dither will allow the peaks to be shaped as required. However, such decisions are at the control of the system designer. The important point is that zero dither is never applied.

Of course, one skilled in the art will appreciate that the overriding principle is that the sum of the inputs to the adding element 60 never be equal to the desired ratio N. That is, an alternative approach would be to input a constant value of (N−1) to the adding element 60 instead of N, and apply dither values of 0 and 2, such that the mean division ratio is still N.

FIG. 6 shows a third clock generation circuit 200 wherein the clock frequency is synthesized using a fractional divide. That is, the overall division factor may not be an integer. In this case, the overall division factor is split into an integer part M and a fractional part y.

The fractional input y is input to a sigma-delta modulator 210 (SDM) as will be familiar to those skilled in the art. The fractional input y may initially be described with a high number of bits. The SDM 210 reduces y to a lower number of bits, but ensures that the average output is equal to y, accurate to a high accuracy. The output of the SDM 210 may be only one bit. Thus, although the instantaneous output of the SDM 210 may be inaccurate, the average output is highly accurate. The output of the SDM 210 is added to the dither in an adding element 220, and this combined signal is added to the integer M in a further adding element 230. The output of the adding element 230 is then used to modulate the clock frequency f_{c}.

Thus, as before, the ÷N block 50 generates an output clock signal at an instantaneous frequency which is equal to the input frequency f_{REF} divided by the output of the adding element 230. This output signal is also used to clock the dither block 70. Again, the average dither applied to the division factor is 0, and so the average frequency of the output clock signal is not shifted, and is equal to f_{REF}/(M+y).

Sigma-delta modulation is one of several possibilities for modulating the fractional input y that will be readily apparent to those skilled in the art. In practice the SDM 210 may be any word length reduction block, such as a truncation or a noise shaper, for example. In the event that the word length reduction block is a truncation, dither may be applied to the fractional input y prior to truncation in order to improve the accuracy of the modulated output.

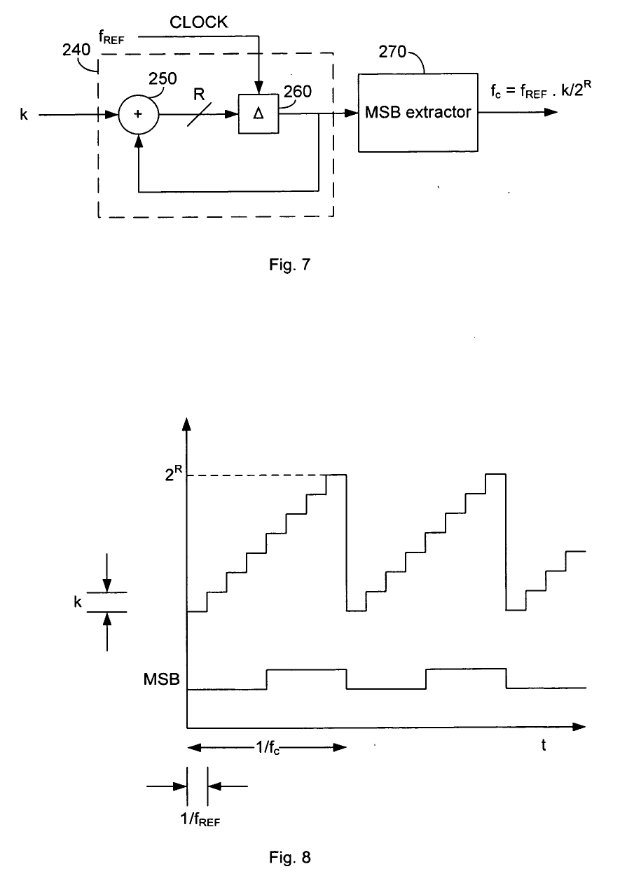

FIG. 7 is a schematic block diagram showing one realization of the ÷N block 50 in the circuits of FIGS. 3, 5 and 6.

The division is realized using a counter 240 and taking the most significant bit (MSB) of the count. An input k is fed to an adder 250, and the signal from the adder 250 fed through a delay element 260. The output from the delay element 260 is fed back to the adder 250. The delay element 260 is clocked at a fixed frequency f_{REF} which is typically much higher than the desired clock frequency. The delay/adder cycle effectively acts as a counter in steps of k. If the input k is R bits long, the highest number the count can reach before repeating is 2^{R}. The most significant bit (MSB) is extracted from the output of the delay element 260 by a MSB extractor 270 and this is used as the new clock signal. Thus the output frequency f_{c} is the input frequency f_{REF} divided by the number of ‘k’s in 2^{R} (f_{c}=f_{REF}×k/2^{R}). By adapting the input k, the output frequency of the MSB, f_{c}, can be altered. Therefore in this embodiment the overall division factor N is 2^{R}/k.

This is shown in more detail in FIG. 8. As the counter counts up, the MSB of the count is taken. The MSB output therefore has a lower frequency that may be adjusted by adjusting the size of the steps taken to reach the maximum value 2^{R}, i.e. k.

The frequency divider described herein preferably forms part of a power converter that is preferably incorporated in an integrated circuit. For example, the integrated circuit may be part of an audio and/or video system, such as an MP3 player, a mobile phone, a camera or a satellite navigation system, and the system can be portable (such as a battery-powered handheld system) or can be mains-powered (such as a hi-fi system or a television receiver) or can be an in-car, in-train, or in-plane entertainment system.

The skilled person will recognise that the above-described apparatus and methods may be embodied as processor control code, for example on a carrier medium such as a disk, CD- or DVD-ROM, programmed memory such as read only memory (firmware), or on a data carrier such as an optical or electrical signal carrier. For many applications, embodiments of the invention will be implemented on a DSP (digital signal processor), ASIC (application specific integrated circuit) or FPGA (field programmable gate array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (very high speed integrated circuit hardware description language). As the skilled person will appreciate, the code may be distributed between a plurality of coupled components in communication with one another. Where appropriate, the embodiments may also be implemented using code running on a field-(re-)programmable analogue array or similar device in order to configure analogue/digital hardware.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

What is claimed is:

1. A frequency divider, comprising:
an input for receiving an input clock signal having a first frequency;
a divider, for generating an output signal having an instantaneous frequency equal to the first frequency divided by an instantaneous division ratio; and
a sequence generator, for generating a sequence of instantaneous division ratios by adding a sequence of instantaneous dither values to an integer value,
wherein said instantaneous division ratios in said sequence have a mean value that is equal to an integer desired ratio, but none of the instantaneous division ratios in said sequence is equal to the integer desired ratio.

2. A frequency divider as claimed in claim 1, further comprising:
a linear feedback shift register, for generating the sequence of instantaneous dither values.

3. A frequency divider as claimed in claim 1, further comprising:
a loop circuit with an unstable feedback loop, for generating the sequence of instantaneous dither values.

4. A frequency divider, comprising:
an input for receiving an input clock signal having a first frequency;
a divider, for generating an output signal having an instantaneous frequency equal to the first frequency divided by an instantaneous division ratio;
a word length reduction block, for receiving a fractional component of a non-integer desired ratio and outputting a sequence of instantaneous modulated outputs; and
a sequence generator, for generating a sequence of instantaneous division ratios by summing a sequence of instantaneous dither values, said sequence of instantaneous modulated outputs and an integer value,
wherein said non-integer desired ratio is equal to the sum of an integer component and said fractional component, said fractional component being less than one,
wherein said instantaneous division ratios in said sequence have a mean value that is equal to the non-integer desired ratio, and
wherein a partial sum of the integer value and the sequence of instantaneous dither values does not equal the integer component of the non-integer desired ratio.

5. A frequency divider as claimed in claim 4, further comprising:
a linear feedback shift register, for generating the sequence of instantaneous dither values.

6. A frequency divider as claimed in claim 4, further comprising:
a loop circuit with an unstable feedback loop, for generating the sequence of instantaneous dither values.

7. A frequency divider as claimed in claim 4, wherein the word length reduction block comprises a sigma-delta modulator.

8. A frequency divider as claimed in claim 4, wherein the word length reduction block comprises a truncation block.

9. A frequency divider as claimed in claim 8, further comprising a dither block for dithering the fractional component prior to truncation.

10. A frequency divider as claimed in claim 4, wherein the word length reduction block comprises a noise shaper.

11. A frequency divider as claimed in claim 4, wherein the instantaneous modulated outputs have one bit.

12. An integrated circuit, comprising a frequency divider as claimed in claim. 1.

13. An audio system, comprising an integrated circuit as claimed in claim 12.

14. An audio system as claimed in claim 13, wherein the audio system is a portable device.

15. An audio system as claimed in claim 13, wherein the audio system is a mains-powered device.

16. An audio system as claimed in claim 13, wherein the audio system is an in-car, in-train, or in-plane entertainment system.

17. A video system, comprising an integrated circuit as claimed in claim 12.

18. A video system as claimed in claim 17, wherein the video system is a portable device.

19. A video system as claimed in claim 17, wherein the video system is a mains-powered device.

20. A video system as claimed in claim 17, wherein the video system is an in-car, in-train, or in-plane entertainment system.

21. A method of frequency synthesis, comprising:
receiving an input signal having a first frequency;
generating a sequence of instantaneous division ratios by adding a sequence of instantaneous dither values to an integer value; and
generating an output signal having an instantaneous frequency equal to the first frequency divided by an instantaneous division ratio;
wherein said instantaneous division ratios in said sequence have a mean value that is equal to an integer desired ratio, but none of the instantaneous division ratios in said sequence is equal to the integer desired ratio.

22. A method of frequency synthesis, comprising:
receiving an input signal having a first frequency;
receiving a fractional component of a non-integer desired ratio and outputting a sequence of instantaneous modulated outputs;
generating a sequence of instantaneous division ratios by summing a sequence of instantaneous dither values, said sequence of instantaneous modulated outputs and an integer value; and
generating an output signal having an instantaneous frequency equal to the first frequency divided by an instantaneous division ratio,
wherein said non-integer desired ratio is equal to the sum of an integer component and said fractional component, said fractional component being less than one,
wherein said instantaneous division ratios in said sequence have a mean value that is equal to the non-integer desired ratio, and
wherein a partial sum of the integer value and the sequence of instantaneous dither values does not equal the integer component of the non-integer desired ratio.

23. A method as claimed in claim 22, wherein the instantaneous modulated outputs have one bit.
